(19) United States
(12) Patent Application Publication
(10) Pub. No.: US 2026/0165053 A1
(43) Pub. Date: Jun. 11, 2026

(54) CONTROL OF ETCH PROFILES IN HIGH ASPECT RATIO HOLES VIA THERMAL ATOMIC LAYER ETCHING

(71) Applicant: Lam Research Corporation, Fremont, CA (US)

(72) Inventors: Andreas FISCHER, Castro Valley, CA (US); Aaron Lynn ROUTZAHN, Fremont, CA (US); Ryan James GASVODA, Portland, OR (US); James SIMS, Tigard, OR (US); Thorsten LILL, Kalaheo, HI (US)

(21) Appl. No.: 18/711,773

(22) PCT Filed: Dec. 2, 2022
(86) PCT No.: PCT/US2022/080857

§ 371 Date: May 20, 2024

Related U.S. Application Data
(60) Provisional application No. 63/265,138, filed on Dec. 8, 2021.

(51) Int. Cl. H10P 50/28; H10P 72/00

(52) U.S. Cl. CPC H10P 50/283; H10P 72/0421

(57) ABSTRACT

Examples are disclosed that relate to thermal atomic layer etching of metal oxides. The method comprises heating a substrate comprising a metal oxide layer as a surface layer, and while heating the substrate, performing an atomic layer etching cycle. The atomic layer etching cycle comprises exposing the metal oxide layer to a fluorinating agent in the absence of a plasma to form a modified surface layer, the metal oxide comprising a group 4 or group 5 transition metal. The atomic layer etching cycle further comprises exposing the modified surface layer to a volatilizing agent in the absence of the plasma to volatilize the modified surface layer.

### BACKGROUND

Advances in integrated circuit manufacturing have been pushing chip architecture in the vertical direction to increase packaging density and reduce costs. For example, advanced memory devices such as three-dimensional (3D) NAND, 3D NOR, or 3D DRAM include multiple layers of devices stacked in an integrated circuit. This trend is increasing the manufacturing challenges by introducing high aspect ratio (HAR) designs in which memory devices are stacked on top of each other.

### SUMMARY

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. Furthermore, the claimed subject matter is not limited to implementations that solve any or all disadvantages noted in any part of this disclosure.

One disclosed example provides a method of performing atomic layer etching. The method comprises, in a three-dimensional semiconductor device fabrication process, heating a substrate comprising a metal oxide layer within a recessed feature of the substrate. The method further comprises, while heating the substrate, performing an atomic layer etching cycle. The atomic layer etching cycle comprises exposing the metal oxide layer to a fluorinating agent in the absence of a plasma to form a modified surface layer. The atomic layer etching cycle further comprises exposing the modified surface layer to a volatilizing agent in the absence of the plasma to volatilize the modified surface layer.

In some such examples, the fluorinating agent alternatively or additionally comprises one or more of hydrogen fluoride, a xenon fluoride, nitrogen trifluoride, a sulfur fluoride, an interhalogen fluoride, or molecular fluorine.

In some such examples, the volatilizing agent alternatively or additionally comprises a chlorine donor, a methyl donor, or a bromine donor.

In some such examples, the volatilizing agent alternatively or additionally comprises one or more of dimethyl aluminum chloride, silicon tetrachloride, trimethylaluminum, boron trichloride, trimethyl chlorosilane hydrogen bromide, trimethylbromosilane, bromosilane, thionyl bromide, sulfur bromide, phosphorus(III) bromide, phosphorus(V) bromide, or molecular bromine.

In some such examples, heating the substrate alternatively or additionally comprises heating the substrate to a temperature greater than 170 degrees Celsius.

In some such examples, exposing the metal oxide layer to the fluorinating agent alternatively or additionally comprises exposing the metal oxide layer to a dose of the fluorinating agent of 0.05 Torr*s or higher.

In some such examples, the recessed feature comprises an aspect ratio of 10:1 (depth: width) or higher.

In some such examples, exposing the modified surface layer to the volatilizing agent alternatively or additionally comprises exposing the modified surface layer to a dose of the volatilizing agent of 0.35 Torr*s or higher.

In some such examples, the atomic layer etching cycle alternatively or additionally comprises an etch rate uniformity as a function of depth within the recessed feature of greater than 85% millitorr or higher.

In some such examples, an etch per cycle (EPC) of the atomic layer etching cycle alternatively or additionally is greater than 0.10 nanometers/cycle.

Another example provides a reactor for performing atomic layer etching. The reactor comprises a processing chamber, a substrate holder comprising a heater, and a controller. The controller comprises stored instructions that are executable to control the atomic layer etching tool to heat a substrate comprising a metal oxide layer within a recessed feature of a substrate, and while heating the substrate, perform an atomic layer etching cycle. The atomic layer etching cycle is performed by exposing the metal oxide layer within the recessed feature of the substrate to a fluorinating agent in the absence of a plasma to form a modified surface layer. The atomic layer etching cycle further comprises exposing the modified surface layer to a volatilizing agent in the absence of the plasma to volatilize the modified surface layer.

In some such examples, the reactor alternatively or additionally comprises a fluorinating agent source, wherein the fluorinating agent source comprises one or more of hydrogen fluoride, a xenon fluoride, nitrogen trifluoride, a sulfur fluoride, an interhalogen fluoride, or molecular fluorine.

In some such examples, the reactor alternatively or additionally comprises a volatilizing agent source, wherein the volatilizing agent source comprises a chlorine donor, a methyl donor, or a bromine donor.

In some such examples, the volatilizing agent source alternatively or additionally comprises one or more of dimethyl aluminum chloride, silicon tetrachloride, trimethylaluminum, boron trichloride, trimethyl chlorosilane, hydrogen bromide, trimethylbromosilane, bromosilane, thionyl bromide, sulfur bromide, phosphorus(III) bromide, phosphorus(V) bromide, or molecular bromine.

In some such examples, instructions alternatively or additionally are executable to heat the substrate to a temperature of 170 degrees Celsius or higher.

In some such examples, the instructions alternatively or additionally are executable to expose the metal oxide layer to a dose of the fluorinating agent of 0.05 Torr*s or higher.

In some such examples, the instructions alternatively or additionally are executable to expose the modified surface layer to a dose of the volatilizing agent of 0.35 Torr*s or higher.

In some such examples, the instructions alternatively or additionally are executable to expose the metal oxide layer to the fluorinating agent comprises by exposing the surface layer to a total pressure of 1 Torr or higher.

Another disclosed example provides a method of performing atomic layer etching. The method comprises, in a three-dimensional semiconductor device fabrication process, placing a substrate in a processing chamber, the substrate comprising a metal oxide layer within a recessed feature of the substrate. The method further comprises heating the substrate comprising a metal oxide layer as a surface layer to a temperature of 170 degrees Celsius or higher. The method further comprises, while heating the substrate, performing an atomic layer etching cycle comprising exposing the metal oxide layer to a fluorinating agent in the absence of a plasma to form a modified surface layer. The atomic layer etching cycle further comprises exposing the modified surface layer to a volatilizing agent in the absence of the plasma at a dose selected to provide an etch rate uniformity as a function of depth within the recessed feature of greater than 85%.

In some such examples, the etch per cycle (EPC) of the atomic layer etching cycle is greater than 0.10 nanometers/cycle.

### BRIEF DESCRIPTION OF THE FIGURES

FIG. 1 shows a schematic depiction of an example low-pressure reactor for performing atomic layer etching (ALE).

FIG. 2 shows a schematic depiction of an example high-pressure reactor for performing atomic layer etching (ALE).

FIG. 3A shows a schematic depiction of an example oxide/nitride (ONON) stack before etching.

FIG. 3B shows the ONON stack of FIG. 3A after holes are etched and a mask for etching has been stripped.

FIG. 3C shows the ONON stack of FIG. 3B after a film of hafnia (HfO₂) has been deposited conformally into the etched holes using atomic layer deposition (ALD).

FIG. 4A shows a cross section of an example full ONON stack with a reactive ion etching (RIE) mask.

FIG. 4B shows a close-up of a top portion of the ONON stack of FIG. 4A.

FIG. 4C shows a close-up of a middle portion of the ONON stack of FIG. 4A.

FIG. 4D shows a close up of a bottom portion of the ONON stack of FIG. 4A.

FIG. 5 illustrates an example dependence of etch per cycle (EPC) on pedestal temperature in an example ALE process conducted at 1 Torr process pressure.

FIG. 6A shows a comparison of example hafnia wet etch rates for films deposited at a high hafnium (Hf) precursor dose and a low Hf precursor dose.

FIG. 6B shows wet etch results for a hafnia film similar to the high dose hafnia film of FIG. 6A in comparison to the initial film thickness profile.

FIG. 7 shows a graph illustrating examples of fluorine concentration in hafnia as a function of hydrogen fluoride (HF) partial pressure at different pedestal temperatures.

FIG. 8A shows examples of high-pressure (1 Torr) HfO₂ EPC profiles at 350° C. in 4 micron (μm) deep holes with an aspect ratio of 55:1 as a function of dimethyl ammonium chloride (DMAC) application time for a sample set with HF exposure of 0.3 Torr*s (150 millitorr (mTorr) for 2 seconds).

FIG. 8B shows example EPC profiles as a function of DMAC application time when fluorination was performed at a HF dose of 24 Torr*s (400 mTorr for 60 seconds).

FIG. 9 shows an example HfO₂ EPC profile at 350° C. in 5 μm deep holes with an aspect ratio of 55:1 as a function of HF application time.

FIG. 10A shows example low-pressure (30 mTorr) EPC profiles at 250° C. in 5 μm deep holes with an aspect ratio of 55:1 as a function of DMAC application time for a sample set with lower HF exposure (0.15 Torr*s) during the modification step.

FIG. 10B shows EPC profiles as a function of DMAC application time (DMAC dose) when fluorination was performed at a higher (0.9 Torr*s) HF exposure during the modification step.

FIG. 11A shows a graph depicting an example dependence of EPC on absolute process pressure in a range between 10 mTorr to 8 Torr.

FIG. 11B shows a graph depicting an etch rate in hafnia of 0.6 nm/cycle achieved by fluorinating the film with a dose of 192 Torr*s followed by a DMAC dose of 5.76 Torr*s.

FIG. 12 shows a flow diagram depicting an example method for performing ALE.

FIG. 13 shows a block diagram depicting an example computing system.

### DETAILED DESCRIPTION

The term “aspect ratio” generally represents a ratio between a depth of a feature of a substrate and an average width of the feature. The term “high aspect ratio” (HAR) generally represents features with depth:width ratios of higher than 10:1.

The term “atomic layer deposition” (ALD) generally represents a process in which a film is formed on a substrate in one or more individual layers by sequentially adsorbing a precursor to a substrate and then chemically transforming the adsorbed precursor to form a film layer.

The term “atomic layer etching” (ALE) generally represents a process in which material is removed a substrate in layer by layer manner by reacting a surface layer with a modifying agent in a self-limiting step to form a modified surface layer, and then volatilizing the modified surface layer. The term “thermal atomic layer etching” (thermal ALE) generally represents an ALE process in which thermal energy is used to drive the ALE process in the absence of a plasma.

The term “atomic layer etching cycle” generally represents a single cycle of reacting a surface of a substrate with a modifying agent to form a modified surface and then volatilizing the modified surface.

The term “carrier substrate” generally represents a full-sized substrate that supports smaller substrate coupons in a processing chamber.

The term “coupon” generally represents a substrate portion that is formed by physically dividing a full-sized substrate into smaller separate portions.

The term “die” generally represents a portion of a substrate on which an integrated circuit is formed. A substrate can be divided into multiple dies, each die having an integrated circuit.

The term “donor” generally represents a molecule that has a leaving group that can be donated to a modified surface layer to volatilize the modified surface layer. Example donors include chlorine donors and bromine donors.

The term “electrostatic chuck pedestal” generally represents a substrate support configured to clamp a substrate to the substrate support using electrostatic force.

The term “etch” generally represents removal of material from a substrate. A wet etch uses a liquid phase solution to remove material from a substrate. A dry etch uses gas phase chemicals to remove material from a substrate.

The term “feature” generally represents topology on a substrate. The term “recessed feature” represents a a feature with an opening that extends below a plane of a substrate surface. Example recessed features include holes and trenches.

The term “feature depth” generally represents a depth with a recessed feature relative to a surface of the substrate. A deeper feature depth is farther from a substrate surface than a shallower feature depth.

The term “fluorinating agent” generally represents a gas-phase chemical that can contribute fluorine to a metal oxide.

The term “hard mask” generally represents a film that is more resistant to etching than polymer photoresists.

The term “isotropic”, “isotropy” and variants thereof generally represent an etch rate that is not dependent upon a surface orientation.

The term “metal oxide” generally represents a material comprising metal and oxygen atoms. Metal oxides include metal silicates.

The term “modification” generally represents a self-limiting chemical transformation of a surface layer of a material by exposure of the material to a chemical modifying agent to form a modified surface layer. The term “modifying agent” generally represents a chemical used in a modification process. Example modifying agents for use in modifying metal oxides include fluorinating agents.

The term “modified surface layer” generally represents a region of a metal oxide layer that has been fluorinated by exposure to a fluorinating agent. A modified surface layer can be volatilized by a volatilization agent in an ALE process.

The term “pedestal” generally represents a substrate holder configured to support a substrate in a processing chamber.

The term “plasma” generally represents an ionized gas comprising cations and free electrons.

The term “processing chamber” generally represents an enclosure in which chemical and/or physical processes are performed on substrates. The pressure, substrate temperature and atmospheric composition within a processing chamber can be controllable to perform the chemical and/or physical processes.

The term “processing gas inlet” generally represents an opening through which processing gases can be introduced into a processing chamber. Example processing gas inlets include showerheads and nozzles.

The term “reactive ion etching (RIE)” generally represents a dry etch process in which a plasma forms reactive ionic species that can chemically react with a substrate surface to remove material from the substrate surface.

The term “reactor” generally represents a processing tool configured to perform atomic layer etching.

The term “showerhead” generally represents a processing chemical outlet comprising a plurality of holes distributed across an area.

The term “strip” generally represents removal of a hard mask film from a substrate.

The term “substrate” generally represents any structure from which layers of material can be removed using ALE.

The term “surface layer” generally represents a volume of material extending into a substrate from a substrate surface that is modified by exposure to a modifying agent in a self-limiting ALE modification step.

The term “three-dimensional semiconductor device” generally represents an integrated circuit comprising multiple layers of stacked component devices. Examples include multiple layers of stacked flash memory cells in a 3D-NAND memory device.

The The term “volatilization” generally represents the conversion of a material from a solid phase to a gas phase.

The term “volatilizing agent” generally represents a chemical agent that can react with a modified surface of a substrate in an ALE process to volatilize the modified surface, thereby removing the modified surface from the substrate.

The term “3D DRAM” is an acronym for three-dimensional dynamic random-access memory.

The term “3D NAND” is an acronym for three-dimensional NOT AND memory, and represents memory architecture based upon NOT AND logic gates.

The term “3D NOR” is an acronym for three-dimensional NOT OR memory, and represents memory architecture based upon NOT OR logic gates.

Fabricating integrated circuits in three dimensions can be facilitated by etch processes that are isotropic and controllable at the atomic level. Such capabilities are advantageous due to the nanometer scale feature sizes of modern devices. To meet these capabilities, examples are disclosed that relate to thermal atomic layer etching (ALE). Thermal ALE involves reacting a material with a modifying chemical to modify a surface layer the material. The modification can be performed isotropically and controllably across the surface of the material. Then, a volatilizing chemical is used to volatilize the modified surface layer. Volatilization removes the modified surface layer, thereby isotropically etching the material.

The disclosed ALE processes are based on a ligand exchange reaction that utilizes thermal activation in the absence of a plasma. In the disclosed examples, the etching of hafnium oxide (HfO₂) layers in high aspect ratio (HAR) hole structures using an ALE process based on hydrogen fluoride (HF) and dimethyl aluminum chloride (DMAC, (CH₃)₂AlCl)) is ddescribed. The disclosed examples can be used to etch other metal oxide materials as well. Examples include other group 4 transition metal oxides and group 5 transition metal oxides, including metal silicates. The terms “group 4” and “group 5” refer to columns of the periodic table of the elements. More specific examples include zirconium oxide (ZrO₂), titanium oxide (TiO₂), niobium oxide (Nb₂O₅), tantalum oxide (Ta₂O₅), hafnium silicate (HfSiO₄), and zirconium silicate (ZrSiO₄). The term “metal oxide” as used herein generally represents a material comprising a metal species and oxygen, and includes silicates.

Thermal ALE processes do not utilize directional plasma steps. Therefore, surfaces inside nanostructures can be etched at highly similar rates regardless of the alignment of the surface with respect to the prevalent flux of reactants or byproducts and their depth inside a structure. To achieve this isotropic etching, in some examples the modification and removal steps of the thermal isotropic ALE process can be permitted enough time to saturate the surface that is to be etched. However, these time periods can be long particularly in hard-to-reach regions of HAR recessed features. This can lead operators of commercial ALE tools into a compromise between achieving perfect etch isotropy by implementing long process steps for reaching saturation and processing a minimum number of devices per hour.

Thus, as described in more detail below, it has been found that conditions used in a surface modification step in thermal isotropic ALE can be varied to vary etch rate without causing a significant impact on isotropy. In some examples, the surface modification step can be performed outside of the saturation regime and still achieve good isotropy in etching rates as a function of depth in a feature. Likewise, it has been found that conditions used in a volatilization step in thermal ALE can be modified to adjust an etch rate profile as a function of feature depth. By varying these and other conditions, such as total processing chamber pressure, both an etch rate and an etch profile as a function of feature depth can be tuned. Example conditions for tuning the modification and volatilization steps are described in more detail below.

### Experimental

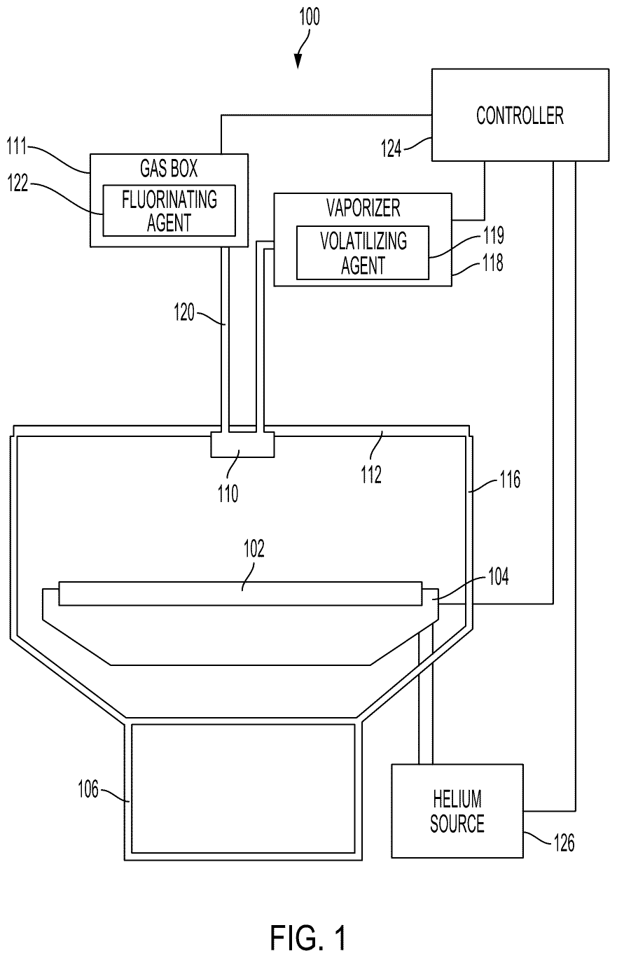

Samples were etched by thermal ALE in one of two reactors depending on a pressure regime for the experiments. For pressures in the range between 10 mTorr and 150 mTorr (hereinafter referred to as a low pressure regime), the experiments were conducted in a modified reactive ion etching (RIE) chamber for 300 mm wafers. A schematic depiction of an example reactor for performing thermal ALE in the low pressure regime is shown as low-pressure reactor 100 in FIG. 1A. More particularly, FIG. 1A illustrates a substrate 102 (e.g. a 300 millimeter semiconductor wafer), an electrostatic chuck pedestal 104, a turbomolecular pump 106, a processing gas inlet 110 connected to a gas box 111, processing chamber 116, a vaporizer 118 comprising a volatilizing agent 119, and a gas line 120 from the gas box 111. A mass flow controller (MFC) (not shown) controls a rate of mass flow of fluorinating agent from a fluorinating agent supply 122 in the gas box 111. The low-pressure reactor 100 further comprises a controller 124. The controller 124 takes the form of a computing system comprising instructions executable to control various aspects of the low-pressure reactor 100. For example, the controller 124 can control a pressure within the processing chamber 116 (e.g. by controlling turbomolecular pump 106 and gas flow rates through the processing gas inlet 110), dose rates of the volatilizing agent and the fluorinating agent, and a substrate temperature.

The substrate 102 was held by the electrostatic chuck pedestal 104. The electrostatic chuck pedestal 104 was heated to a temperature between 150° C. and 280° C. Heat was transferred by introducing helium gas (from a helium source 126) between the electrostatic chuck pedestal 104 and the backside surface of the substrate 102. This helps to transfer heat at process pressures in the millitorr range. The turbomolecular pump 106 could maintain pressures between 1 and 500 mTorr. The volatilizing agent 119 (for example, DMAC) can be converted from liquid to gas in the vaporizer 118. The volatilizing agent was drawn to the substrate 102 by the vacuum maintained by the turbomolecular pump 106. The fluorinating agent (for example, hydrogen fluoride (HF)) was delivered from the gas box 111. The fluorinating agent flow was controlled via a mass flow controller (not shown). The fluorinating agent and the volatilizing agent were injected through the processing gas inlet 110, which was located above a center of the substrate 102. Flows rates between 50 and 500 sccm (standard cubic centimeters) were used for volatilizing agent vapor as well as for fluorinating agent. No background gas such as nitrogen was used in the low-pressure reactor 100. While hydrogen fluoride was used in the disclosed examples as a fluorinating agent to form a modified surface layer by fluorinating the surface layer, in other examples other chemicals can be used to modify a surface for subsequent volatilization. Examples of other fluorinating agents include xenon fluorides (for example, xenon hexafluoride (XeF₆)), sulfur fluorides (e.g. sulfur hexafluoride (SF₆)) nitrogen trifluoride (NF₃), interhalogen fluorides (e.g. chlorine trifluoride (ClF₃)), and molecular fluorine (F₂). Likewise, while DMAC was used as chlorine donor to volatilize the modified surface layer, in other examples other chlorine donors can be used. Examples include boron trichloride (BCl₃), silicon tetrachloride (SiCl₄), and trimethyl chlorosilane ((CH₃)₃ClSi). Further, in some examples, a bromine donor can be used instead of a chlorine donor. Example bromine donors include hydrogen bromide (HBr), trimethylbromosilane, bromosilane, thionyl bromide, sulfur bromide, phosphorus(III) bromide, phosphorus(V) bromide, and molecular bromine (Br₂). Such chemicals for volatilizing the modified surface layer can be referred to generally as volatilizing agents. The volatizing agent can undergo a ligand exchange reaction with metal atoms in the modified surface layer to form volatile products. Example volatile products formed in the ALE of hafnia can include HfClF₃ and dimethyl aluminum fluoride. In other examples, an organic ligand donor, such as a methyl donor, can be used. An example of a methyl donor is trimethylaluminum (TMA).

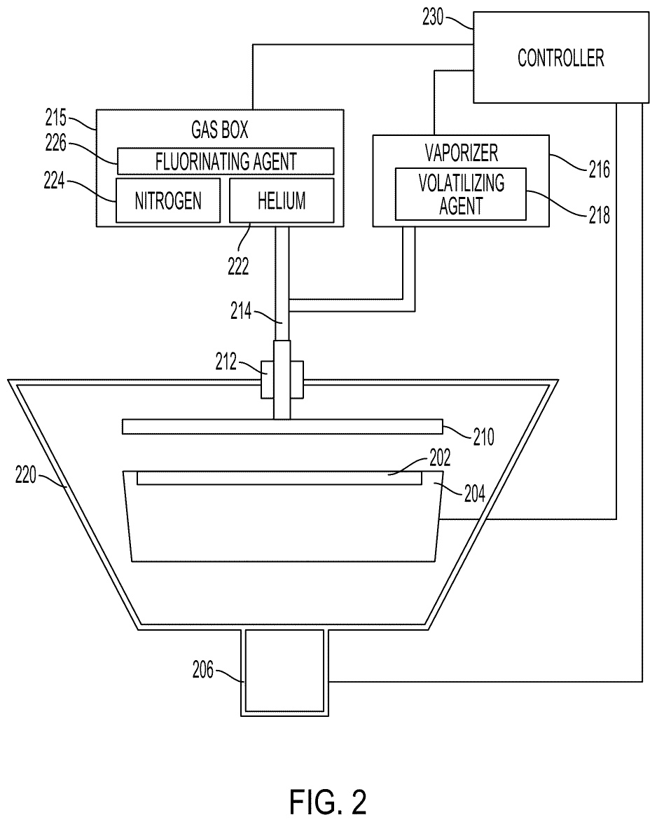

Referring next to FIG. 2, for pressures above 350 mTorr, the experiments were conducted in a modified deposition chamber used as a high-pressure reactor 200. FIG. 2 schematically illustrates a substrate 202 (for example, a 300 millimeter semiconductor wafer), an aluminum pedestal heater 204, a mechanical vacuum pump 206, a gas injection showerhead 210, a showerhead collar purge gas inlet 212, a process gas inlet 214 configured to provide processing gases from a gas box 215 to the gas injection showerhead 210, a vaporizer 216 configured to provide volatilizing agent 218 to the gas injection showerhead 210, and processing chamber 220. A controller 230 comprising a computing system includes instructions executable to control various aspects of the high-pressure reactor 200. For example, the controller 230 can control a pressure within the processing chamber 220 (e.g. by controlling mechanical vacuum pump 206 and gas flow rates through the gas injection showerhead 210), dose rates of the volatilizing agent and the fluorinating agent, and a substrate temperatures.

The substrate 202 was placed on the aluminum pedestal heater 204, which heated the wafer. Once the substrate 202 was placed onto the aluminum pedestal heater 204, helium 222 was flowed over the substrate for 20 seconds at 1250 sccm at a pressure of 2.0 Torr in a helium soak step. This aided in transferring heat from the aluminum pedestal heater 204 to the substrate 202. The aluminum pedestal heater 204 setpoint could be varied between room temp and 400° C. A position-controlled butterfly valve (not shown) maintained the chamber pressure at the desired pressure setpoint. Pressure setpoints between ranged between 350 mTorr and 8.0 Torr were used. After the helium soak step, the ALE process was started. All process gases (helium 222, nitrogen 224, volatilizing agent 218 (for example, DMAC), and fluorinating agent 226 (for example, hydrogen fluoride) in these examples) were delivered through the gas injection showerhead and controlled via mass flow controllers (not shown in FIG. 2). A low back pressure mass flow controller (not shown) was used to control flow of the volatilizing agent into the high-pressure reactor 200. All hydrogen fluoride and nitrogen flows were between 50 and 1000 sccm. The DMAC flow was held constant at 50 sccm. While the experiments disclosed herein were performed in processing chambers that were modified to make low-pressure reactor 100 and high-pressure reactor 200, in other examples thermal ALE can be performed in any other suitable processing tool than the disclosed processing tools.

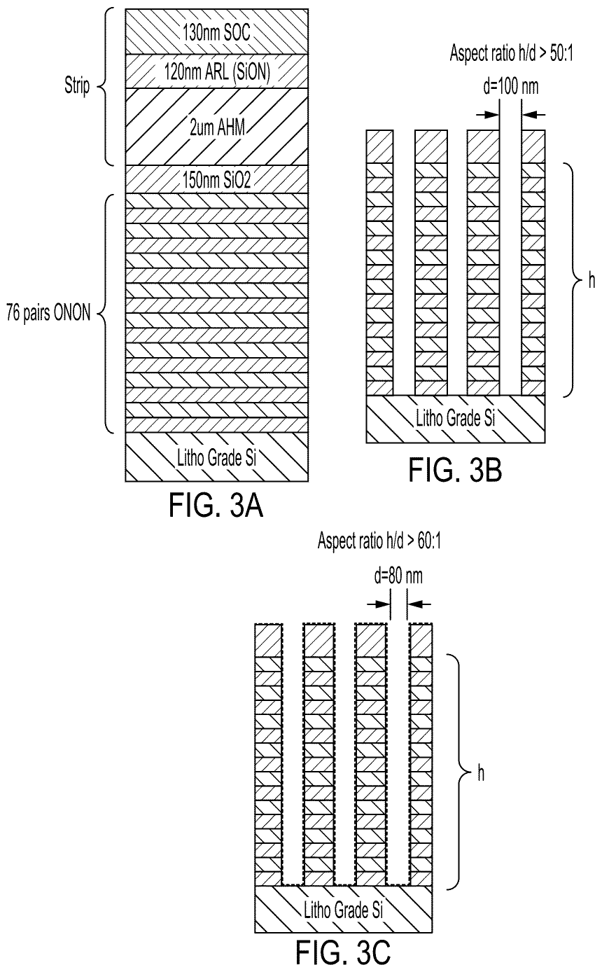

To measure thermal ALE etch rates in high aspect ratio structures, substrates with dies containing 5 μm tall ONON (oxide-nitride-oxide-nitride) stacks were generated. These stacks comprised 76 ON (oxide-nitride) pairs covered with a mask patterned with 100 nm holes. Approximately 5 uμm deep holes were etched via high-energy reactive ion etching (RIE). These holes are an example of a recessed feature of a substrate. After hole formation was completed, the hard mask was removed with an oxygen (O₂) based strip process in a strip tool. After cutting the etched and stripped wafer in coupons of size 30 mm×15 mm, the coupons were then coated with an atomic layer deposition (ALD) hafnia (HfO₂) film. The coupons were then either bonded to a silicon carrier substrate with gallium for experiments in the low-pressure reactor or placed on a special carrier wafer with a pocket that was previously etched into it for experiments in the high-pressure reactor, respectively. When the hafnia thickness was included in the calculation, the structures had an initial aspect ratio prior to the start of ALE of approximately 62:1 (5,000 nm deep with an initial diameter of 80 nm). A schematic of the sample preparation process is shown in FIGS. 3A-3C. More particularly, FIG. 3A shows schematics of a 76 pair ONON stack before RIE. FIG. 3B shows the same stack after 100 nm holes are etched via RIE and mask has been stripped. FIG. 3C further shows a cross sectional view of the holes after ˜10 nm hafnia (orange coating) has been deposited conformally into same holes via ALD.

After performing ALE, the coupons were filled with a flowable carbon and imaged with Transmission Electron Microscopy (TEM). The region to be imaged was removed from the sample by Focused Ion Beam (FIB) milling and mounted to a TEM grid. Imaging was done at 200 keV (kilo electron volt) and 50,000×magnification. Images were analyzed and the corresponding etch rates graphed versus their depth location inside the ONON stack. The thickness of the hafnia film was measured perpendicular to the underlying substrate on both oxide and nitride layers. No discernable difference in hafnia film thickness was detected with respect to their location on either the oxide or the nitride layer, respectively. At least 30 measurements were performed at each depth to assure good statistical significance of the hafnia thickness data.

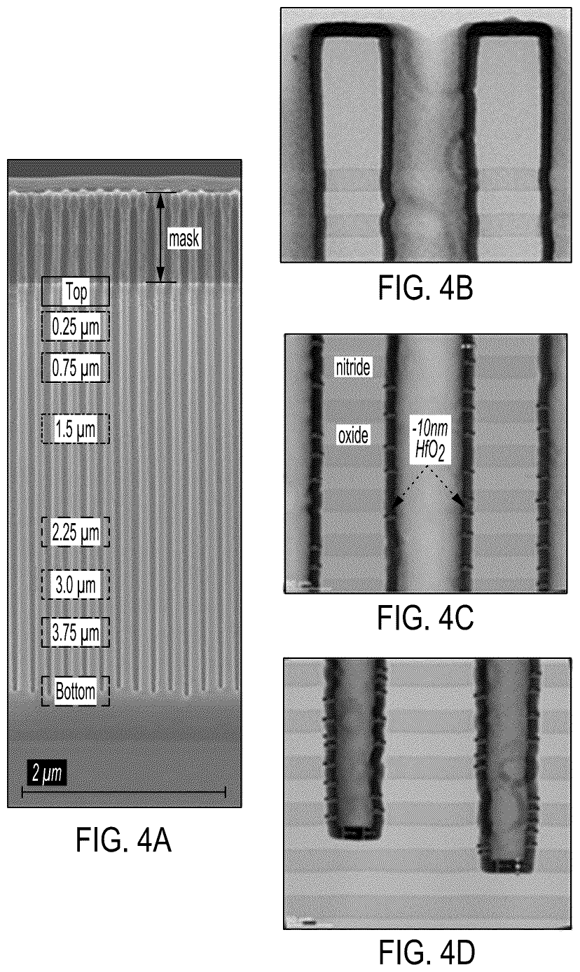

TEM cross sections of a sample together with measurement locations after ALE are shown in FIGS. 4A-4D. More particularly, FIG. 4A shows a cross section of a full ONON stack with RIE mask and post ALE measurement locations. FIG. 4B shows a close-up view of a top portion of the ONON stack. The top portion is indicated by the label “Top” in FIG. 4A. FIG. 4C shows a close-up of a mid-section of the ONON stack. FIG. 4D shows a close-up of a bottom portion of the ONON stack. The bottom portion is indicated by the label “Bottom” in FIG. 4A. In FIG. 4C, the oxide and nitride bands as well as the 10 nm hafnia layer deposited prior to ALE are labeled. The ONON structure is recognizable by the light-and-dark grey bands in FIGS. 4B-4D. Also shown in FIGS. 4B-4D is the hafnia layer, visible as a black film inside the holes.

A Thermo Fisher Scientific Theta 300 standalone x-ray photoelectron spectroscopy (XPS) tool with a monochromatic Al k_{α} x-ray source at 1486.7eV was utilized to characterize the surface composition of the hafnia films prior to performing isotropic thermal ALE. There was a queue time in air of up to 30 minutes between sample processing and XPS measurements when samples were fluorinated with the low-pressure reactor. Queue-times of up to 24 hours occurred when samples were fluorinated with the high-pressure reactor. By performing controlled experiments, it was established that the queue-time impact on fluorine levels in hafnia films was negligible up to at least 72 hours after fluorination when samples were kept in ambient clean room conditions of ˜20° C. and ˜40% relative humidity.

### Results and Discussion

In order to generate meaningful etch rate data inside high aspect ratio nano structures such as the ˜80 nm holes in the ONON stacks described above, care was taken to deposit hafnia films with high quality throughout the entire depth of each hole so that the etch rate results would not be affected by varying initial film thicknesses within a structure, grain sizes, hafnium:oxygen ratio, or crystallinity. Other studies have shown that thermal ALE etch rates are a function of material crystallinity for aluminum oxide (Al₂O₃), hafnia and zirconium oxide. Multiple parameters can have an impact on film quality during growth. Example parameters include the precursor type, growth rate, dosing, and the substrate temperature. ALE etch-per-cycle (EPC) measurements were determined as a function of substrate temperature for ALD hafnia films deposited at temperatures of 250° C. and 300° C.

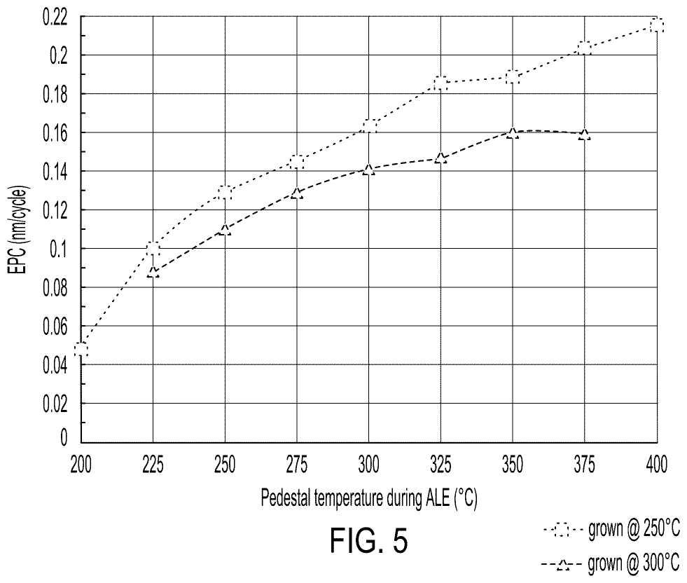

FIG. 5 illustrates dependence of EPC on pedestal temperature at 1 Torr process pressure. In FIG. 5, the data series with lower EPCs correspond to the 300° C. hafnia film. The lower EPC of this sample shows that this film exhibited better film quality. As a possible mechanism, the film grown at higher temperatures may have had less hydrogen incorporation during growth and/or higher crystallinity. Lower hydrogen incorporation can reduce the EPC during etch. FIG. 5 shows that the reduced EPC for the 300° C. hafnia was lower throughout the entire ALE temperature range compared to the 250° C. film. The overall difference in EPC between these two films dropped with temperature from a high of 25% at 375° C. to a low of 10% at 225° C.

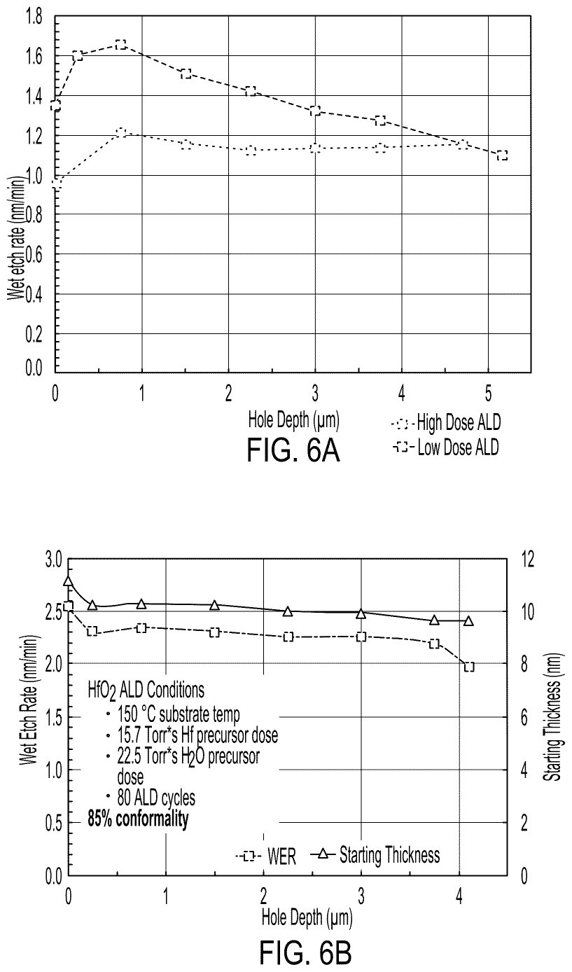

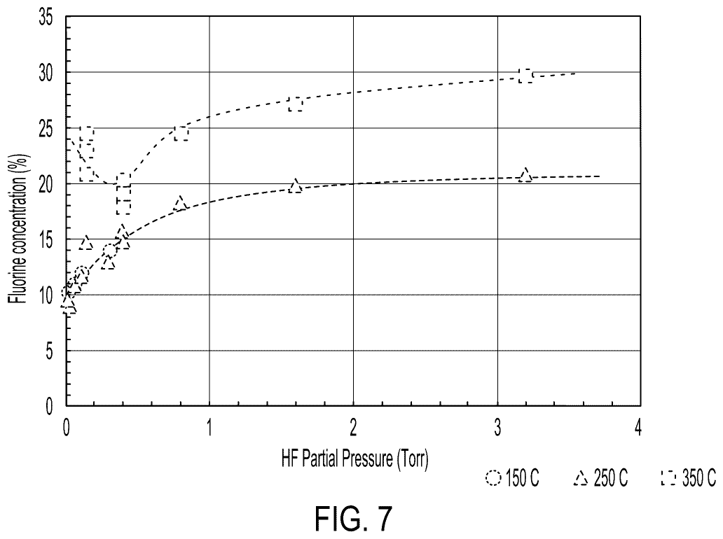

In addition to substrate temperature during film growth, the precursor dose played an important role in controlling the quality of the hafnia films. The hafnia film quality was assessed by etching hafnia films in a 100:1 water-diluted hydrogen-fluoride solution for three minutes at room temperature. FIGS. 6A and 6B show results from experiments in which wet etch rates were used as a measure of film quality deposited inside nanostructures. More particularly, FIG. 6A shows a comparison of hafnia wet etch rates for hafnia films deposited by ALD at a higher hafnium precursor dose (15.7 Torr*s hafnia and 22.5 Torr*s water (H₂O) precursors) and a lower hafnium precursor dose (7 Torr*s Hf and 7 Torr*s H₂O precursors). The hafnium precursor used was tetrakis(ethylmethylamino)hafnium (TEMAH). FIG. 6B shows wet etch results in comparison to the initial film thickness profile. Growth conditions for that film are given in the lower left of the graph of FIG. 7B. The growth conditions for the hafnia film included a substrate (pedestal) temperature of 150° C. and the above-listed higher dose conditions.

Of the two representative wet etch rates shown in FIG. 6A, clearly visible is the higher wet etch rate uniformity in the 80 nm hole structure for which the hafnia was previously deposited at a higher precursor dose. FIG. 6B shows the wet etch rate for a higher precursor dose film deposited under similar conditions and the corresponding initial film thickness. Note the relatively flat profile. Total conformality top to bottom was better than 85%. All material used for the high aspect ratio ALE studies disclosed herein utilized films of quality and conformality similar to the one shown in the experimental results of FIG. 6B.

A final correlation performed before turning to actual nanostructures for ALE processing was the fluorination efficiency of hafnia. Anhydrous hydrogen fluoride vapor was used as a fluorinating agent to fluorinate the samples. An amount of bonded fluorine left behind on blanket hafnia films as a function of substrate temperature and hydrogen fluoride partial pressure was measured utilizing XPS. As some of these films were fluorinated in the high-pressure reactor several hundred kilometers away from the site the XPS measurements were performed, it was verified first that the influence of an air exposure time of up to 72 hours had no discernable impact on the final fluorine concentration in the films.

The XPS results of the fluorination tests are displayed in FIG. 7. More particularly, FIG. 7 shows fluorine concentration in hafnia after fluorination with hydrogen fluoride. An increase was observed in bonded fluorine concentration when the substrate temperature was increased from 250° C. to 350° C. However, there was no discernable difference between the 150° C. and 250° C. samples (see FIG. 7). This behavior can indicate that there is a certain ‘activation’ required to significantly drive fluorine uptake into the hafnia films past the initial uptake from reactivity of hydrogen fluoride with the surface hydroxyl (OH) groups. This behavior is in contrast to findings for Al₂O₃ in which a steady but slight reduction in fluorine with temperature was observed. This may be attributable to an increased desorption rate as a function of temperature increase. It is noted, however, that the fluorine content vs. temperature for Al₂O₃ was performed between 150° C. and 250° C. and may have not captured the ‘activation’ or minimum temperature for a significant driving of the HF reaction with Al₂O₃.

In addition to temperature, the hydrogen fluoride partial pressure also had a determining effect on the fluorine content of the films. A dependence of process pressure on the fluorination thickness and the resulting etch amount per cycle reported for aluminum oxide for the pressure range between 0.15 Torr to 8 Torr As pressure sets up the dose during fluorination, in the present work, fluorine concentrations of up to 30% could be achieved when a partial hydrogen fluoride pressure of 3.2 Torr (8 Torr total pressure) was applied to the samples. This amount is higher than the 8 Torr results of 10% reported to be achieved on Al₂O₃, perhaps due to the difference in material and the somewhat higher temperature used in the present examples (350° C. instead of 300° C. reported for Al₂O₃). In the present examples, 30% fluorine content also could be reached in hafnia films as measured with XPS when a zero-bias ICP plasma was used with hydrogen fluoride as the feed gas. The plasma result matches the high-pressure thermal result. Thus, this level of fluorine content may represent an upper limit of fluorination due to the high efficiency of plasma in providing reactive fluorine to a substrate surface. This may indicate that fluorination by thermal ALE may be as effective as fluorination by plasma enhanced ALE, but without the directional effects of a plasma.

Relatively higher fluorine levels can be advantageous compared to relatively lower fluorine levels when high aspect ratio structures are to be fluorinated. This is for at least the reason that the relatively higher fluorine levels drive surfaces deeper within features to a near-saturation level faster. This can reduce depth dependence of EPC during etching. In addition, relatively higher fluorine levels can help to obtain relatively higher etch rates per cycle. This can help to attain relatively higher tool throughput in industrial applications.

Next are presented results and discussion regarding effects of dosing, controlled by process step times, on the depth uniformity in EPC. Both the hydrogen fluoride-based modification step length as well as the DMAC-based removal step length were controlled independently.

EPCs were determined by subtracting the hafnia film thickness inside the vertical 80 nm holes of the substrate coupons after ALE processing from the film thickness of an unprocessed structure. This computation was followed by dividing the delta by the number of ALE cycles. Between 15 and 20 cycles were chosen to obtain meaningful EPC values and to minimize start-up effects.

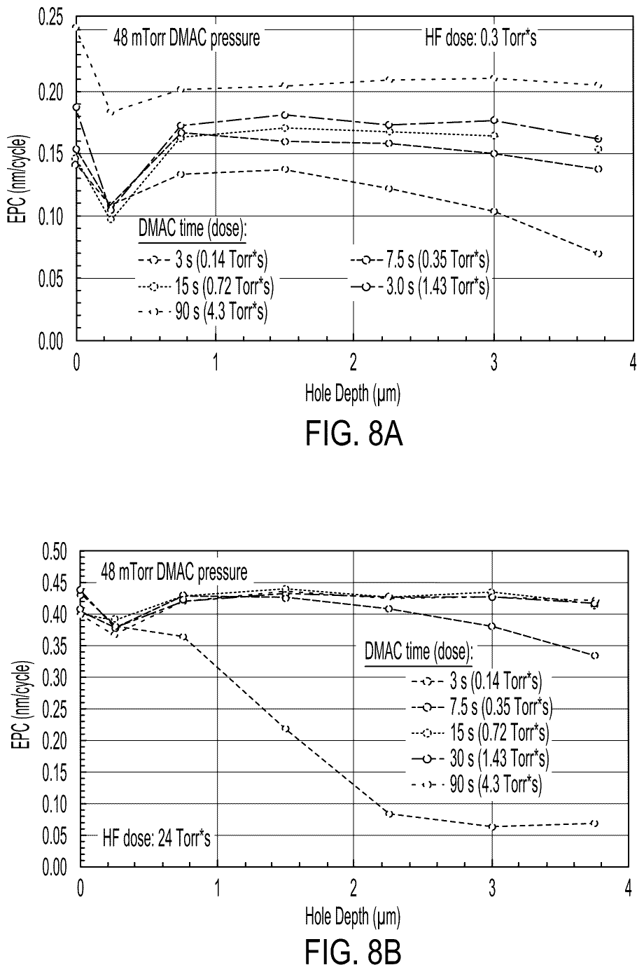

Using the high-pressure reactor 200 of FIG. 2, both reactants were applied with nitrogen as a background gas. This established an absolute reactor pressure of 1 Torr. Partial HF pressures were 150 mTorr and 400 mTorr, respectively for the lower hydrogen fluoride dose and the higher hydrogen fluoride dose. The corresponding EPC data for the lower hydrogen fluoride dose are shown in FIG. 8A. The corresponding EPC data for the higher hydrogen fluoride dose are shown in FIG. 8B. The partial pressure of DMAC was maintained at 48 mTorr for both sets of experiments. In all experiments, a constant substrate temperature of 350° C. was maintained throughout the entire ALE process.

EPCs were lower in the lower hydrogen fluoride dose (0.3 Torr*s) set of experiments. This can indicate that the fluorination was performed in a non-saturated process regime. In this regime, however, depth profiles in etch rate could be tuned by varying the DMAC dose. For example, a bottom-slow depth profile in the etch rate was obtained at a DMAC dose of 0.14 Torr*s. A flatter depth profile in the etch rate was obtained for the highest tested DMAC dose of 1.43 Torr*s.

In a second set of experiments, referring to shown in FIG. 8B, the substrate coupons received a hydrogen fluoride dose of 24 Torr*s. This was achieved by exposing the substrate coupons to hydrogen fluoride vapor at a partial pressure of 400 mTorr for 60 seconds. In general, EPCs are higher by roughly a factor of two. This indicates that hydrogen fluoride exposure was closer to fluorine saturation. For DMAC doses greater than 0.72 Torr*s (application time of 15 seconds in this experiment), a flat etch profile could be achieved. Lower DMAC doses led to a reduction of etch rate deeper within the holes. This may have been due to precursor depletion. This results in a skewed etch profile similar to the lower hydrogen fluoride dose experiments.

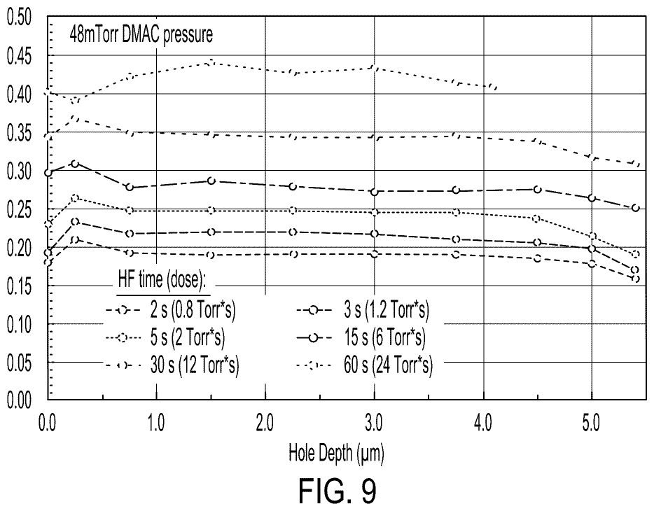

A complementary set of EPC measurements was performed on samples that received a fixed DMAC dose of 0.72 Torr*s during the removal step but had the hydrogen fluoride dose varied from a low exposure of 0.8 Torr*s to a high one of 24 Torr*s. This DMAC dose was chosen as it provided relatively uniform flat EPC results as function of feature depth in the previous set of experiments. The absolute pressure was again controlled to be 1 Torr with a substrate temperature for both, modification and removal steps, of 350° C. FIG. 8 shows hafnia EPC profile at 350° C. in 5 μm deep holes with an aspect ratio of 55:1 as a function of hydrogen fluoride application time (dosing). Partial hydrogen fluoride pressure was maintained at 400 mTorr with an absolute pressure of 1 Torr, using nitrogen as a background gas. The EPC profiles remained flat even for process regimes well outside hydrogen fluoride saturation. As shown in FIG. 9, all etch profiles stayed relatively flat due to sufficient DMAC dosing during the removal step. The hydrogen fluoride dose had no observable impact on the etch rate profile. The hydrogen fluoride dose did, however, drive the etch rate per cycle higher with dosing.

Comparing all three sets of experiments shown in FIGS. 8A, 8B and 9, it can be seen that controlling DMAC dosing can allow controlling of the etch rate profile in high aspect ratio nanostructures. A relatively flatter etch rate profile can be achieved with DMAC dosing close to saturation. Sub-saturation doses can result in slower EPCs that depend on the depth location in the structure, which leads a relatively less flat etch rate profile. The analogous experiments using the hydrogen fluoride exposure time as a parameter did not produce this result. Even for ultra-low hydrogen fluoride doses of 0.8 Torr*s corresponding to an exposure time of 2 seconds, the etch rate profiles remained flat and increased uniformly with hydrogen fluoride dose.

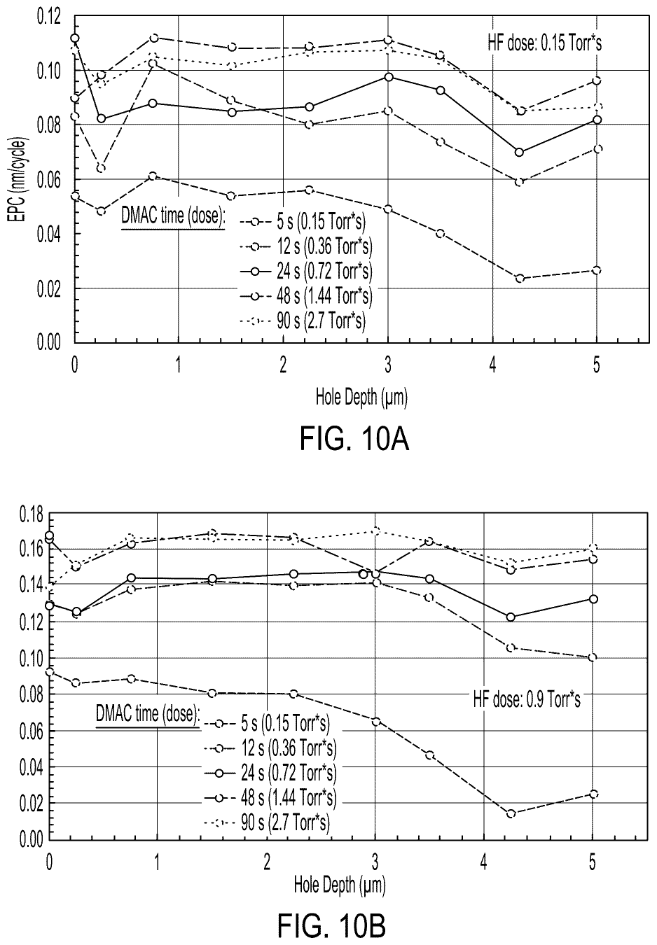

Another set of experiments was performed at low pressure and lower substrate temperature in the reactor depicted in FIG. 1. Substrates were clamped on an electrostatic chuck pedestal and the pedestal temperature was controlled to be constant at 250° C. Unlike in the ALE processes performed in reactor of FIG. 2, no background gas was applied, resulting in lower process pressures. The process pressures were typically of 30 mTorr. Hydrogen fluoride gas was delivered from a commercial gas box controlling the flow via a mass flow controller. DMAC was vacuum drawn into the reactor, again, without a carrier gas. As before, one set of tests was run at a low fluorination dose of 0.15 Torr*s. This constituted approximately half of the dose compared to the lower dose condition in the high-pressure reactor study described above. The results of the 0.15 Torr*s dose experiments are shown in FIG. 10A. The high hydrogen fluoride dose here was 0.9 Torr*s (30 mTorr for 30 seconds) due to the lower reactor pressure. The results of the 0.9 Torr*s dose experiments are shown in FIG. 10B. The hafnia EPC results as determined via cross sectional TEM analysis are shown in FIGS. 10A and 10B.

In general, the results from the low-pressure reactor of FIG. 1 ended up being noisier than the results from the high-pressure reactor of FIG. 2. EPCs from the high-dose experiment were roughly comparable to the results described above, with a reasonably flat etch profile when the higher DMAC doses shown in FIGS. 10A and 10B were applied. For the lower DMAC doses shown in FIGS. 10A and 10B, the EPC dropped, particularly at the bottom of the structures. This may indicate that the etch rate profile as a function of depth can be tuned.

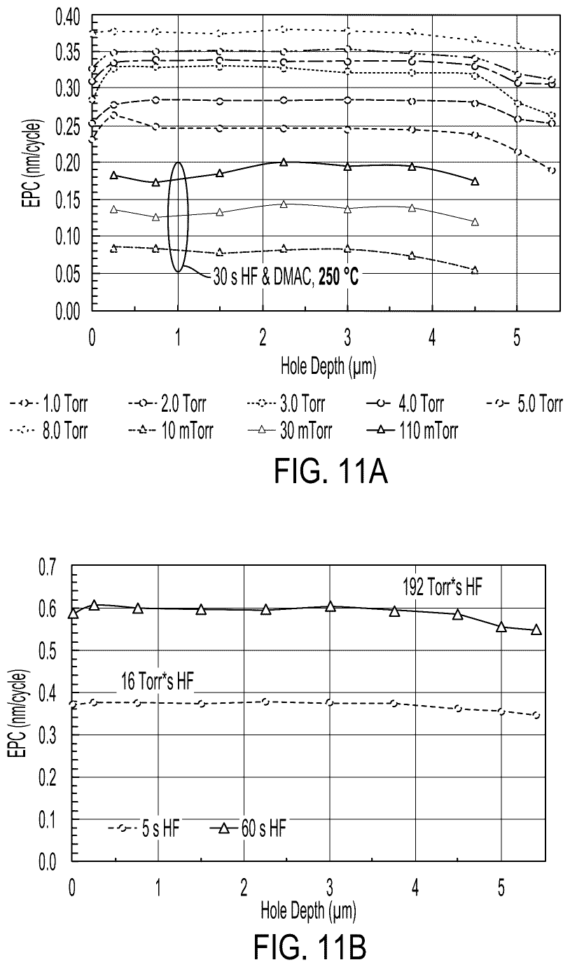

In another set of experiments, an impact of process pressure on etch rate and profile was studied. The process pressure was varied between 10 mTorr and 8 Torr, with the fluorination and DMAC exposure steps kept isobaric to one another. Etch rate profiles were measured using cross sectional TEM analysis. The samples were etched at a substrate temperature of 350° C. unless stated otherwise. In view of the wide pressure range, the reactors of FIG. 1 and FIG. 2 both were utilized to carry out these experiments. The results, shown in FIG. 11A, display the strong dependence of EPC on process pressure. EPCs could be boosted from 0.08 nm/cycle at 10 mTorr to nearly 0.4 nm/cycle at 8 Torr. As a sufficiently large DMAC dose was used for all samples (15 s at 48 mTorr DMAC partial pressure per Torr of chamber pressure), all etch rate profiles are relatively flat compared to the use of lower DMAC partial pressures. As the EPC is of interest in semiconductor manufacturing due to its impact on tool throughput, it was attempted to boost the etch rate as high as possible by super-fluorinating a sample. A hydrogen fluoride dose of 192 Torr*s (60 s of HF at a partial pressure of 3.2 Torr) resulted in an EPC of 0.6 nm/cycle implying that more than one lattice constant (0.51 nm) was recessed per ALE cycle.

FIGS. 11A and 11B further shows a dependence of EPCs on absolute process pressure in the range between 10 mTorr to 8 Torr. For data in the Torr range, a DMAC dose of 0.72 Torr*s was applied for each Torr of chamber pressure (FIG. 11A). An etch rate in hafnia of 0.6 nm/cycle was achieved by fluorinating the film with a dose of 192 Torr*s (60 s at a partial HF pressure of 3.2 Torr) followed by a DMAC dose of 5.76 Torr*s (384 mTorr partial pressure of DMAC for 15 s) (FIG. 11B).

Thus, the disclosed examples can provide for thermal isotropic ALE as a viable tool for etching high aspect ratio structures. A higher pressure process regime can provide for higher etch rates compared a lower pressure process regime. Lateral etch rate profiles in HAR structures as a function of depth can be tuned by varying DMAC. It was found that substantially flat etch profiles were obtained beyond a threshold DMAC dose (0.72 Torr*s in the experiments disclosed herein). Profile control was less sensitive to hydrogen fluoride dosing. However, EPC was sensitive to hydrogen fluoride dosing. In a sample with maximum fluorination performed at 8 Torr of absolute chamber pressure, an isotropic etch amount of 0.6 nm per cycle, more than the size of the lattice constant for hafnia, was achieved.

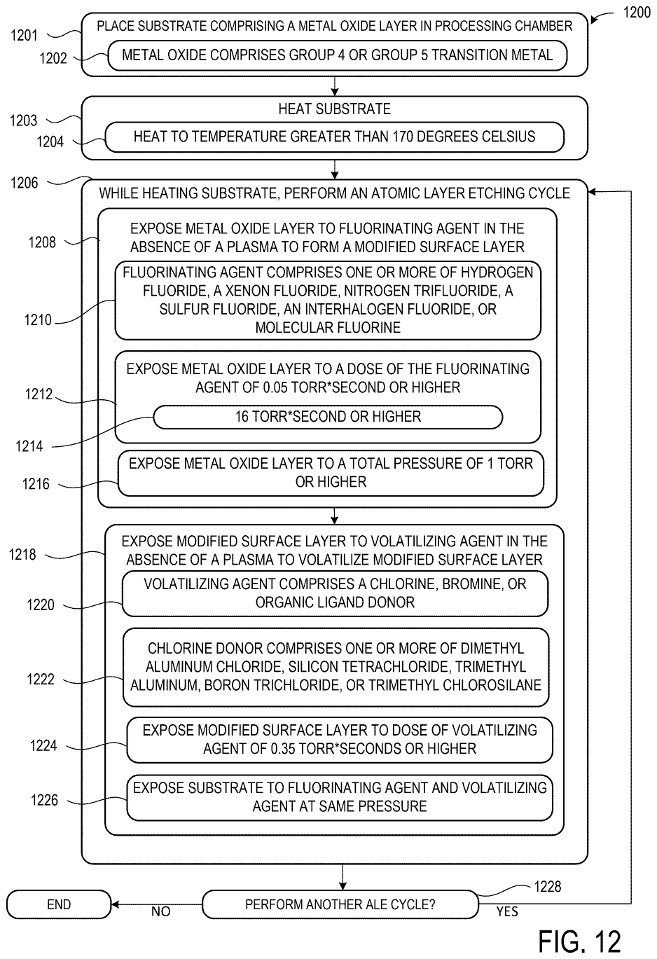

FIG. 12 shows a flow diagram depicting an example method 1200 for performing atomic layer etching. Method 1200 comprises, at step 1201, placing the substrate in a processing chamber. The substrate comprises a metal oxide layer as a surface layer. The metal oxide layer can be at least partially located in a high aspect ratio feature in some examples. Example high aspect ratio features include holes and trenches formed during the fabrication of 3D integrated circuits. Such features can have aspect ratios of 10:1 (depth:width) or higher. Example 3D integrated circuits include 3D-NAND memory, 3D-NOR memory, and 3D-DRAM memory. The metal oxide can comprise a group 4 or group 5 transition metal, as indicated at 1202. More specific examples of the metal oxide include hafnia, zirconium oxide, titanium oxide, niobium oxide, tantalum oxide, hafnium silicate, and zirconium silicate.

Method 1200 further comprises, at step 1203, heating the substrate. The substrate can be heated to any suitable temperature. In some examples, the substrate can be heated to a temperature of 170 degrees Celsius or higher, as indicated at 1204. In some such examples, the substrate can be heated to a temperature of 250 degrees Celsius or higher. At higher temperatures, fluorination of the metal oxide layer can occur more rapidly.

Method 1200 further comprises, at step 1206, while heating the substrate, performing an ALE cycle. The ALE cycle comprises, at step 1208, exposing the metal oxide layer to a fluorinating agent to form a modified surface layer. As indicated at 1210, in some examples, the fluorinating agent comprises one or more of hydrogen fluoride, a xenon fluoride (e.g. xenon difluoride (XeF₂), xenon tetrafluoride (XeF₄), or xenon hexafluoride (XeF₆)), nitrogen trifluoride, a sulfur fluoride (e.g. sulfur tetrafluoride (SF₄) or sulfur hexafluoride (SF₆), an interhalogen fluoride (e.g. chlorine trifluoride (ClF₃) or chlorine pentafluoride (ClF₅)), or molecular fluorine. In some examples, as indicated at 1212, the metal oxide layer is exposed to a dose of the fluorinating agent of 0 .05 Torr*s or higher. In some such examples, as indicated at 1214, the metal oxide layer is exposed to a dose of the dose of the fluorinating agent of 16 Torr*s or higher. The use of a higher dose of the fluorinating agent can provide for higher EPCs. Further, in some examples, the metal oxide layer is exposed to a total pressure of 1 Torr or higher during exposure to the fluorinating agent. Total pressures of 1 Torr or higher can lead to higher EPCs. However, in other examples, lower total pressures can be used.

Continuing, after exposing the metal oxide layer to the fluorinating agent, the processing chamber can optionally be purged with a purge gas. Example purge gases include nitrogen and argon. Then, at step 1218, method 1200 includes exposing the modified surface layer to a volatilizing agent in the absence of the plasma to volatilize the modified surface layer. As indicated at 1220, the volatilizing agent can comprise a chlorine donor, an organic ligand donor (e.g. a methyl donor), or a bromine donor. In some examples, the chlorine donor can comprise, at 1222, one or more of DMAC, silicon tetrachloride, boron trichloride, or trimethyl chlorosilane. Further, in some examples, the bromine donor can comprise one or more of hydrogen bromide, trimethylbromosilane, bromosilane, thionyl bromide, sulfur bromide, phosphorus(III) bromide, phosphorus(V) bromide, or molecular bromine. In yet further examples, the methyl donor can comprise trimethyl aluminum. In some examples, as indicated at 1224, the modified surface layer can be exposed to a dose of the volatilizing agent of 0.35 Torr*s or higher. Such doses can lead to more uniform EPC rates as a function of feature depth. In other examples, a volatilizing agent dose of less than 0.35 Torr*s can be used. Lower doses can allow a EPC rate as a function of feature depth to be varied.

In some examples, the modified surface layer is exposed to a total pressure of 1 Torr or higher during exposure to the volatilizing agent. In other examples, lower total pressures can be used. Further, as indicated at 1226, in some examples the substrate is exposed to the fluorinating agent and the volatilizing agent at a same total pressure. The use of a same total pressure for exposure to the fluorinating agent and the volatilizing agent can help to reduce processing times, as no time is taken in changing and then stabilizing a processing chamber pressure.

After completing the ALE cycle, method 1200 comprises, at 1228, determining whether to perform another ALE cycle. If it is determined to perform another ALE cycle, then method 1200 returns to 1206, where the metal oxide layer is again exposed to the fluorinating agent. On the other hand, if it is determined not to perform another ALE cycle, then method 1200 ends. In some examples, an EPC of greater than 0.10 nanometers/cycle can be achieved. In some such examples, an EPC of greater than 3.6 nanometers/cycle can be achieved. In some such examples, an EPC of 0.6 nanometers/cycle can be achieved. Further, in some examples, an etch rate uniformity as a function of depth within the recessed feature of greater than 85% can be achieved.

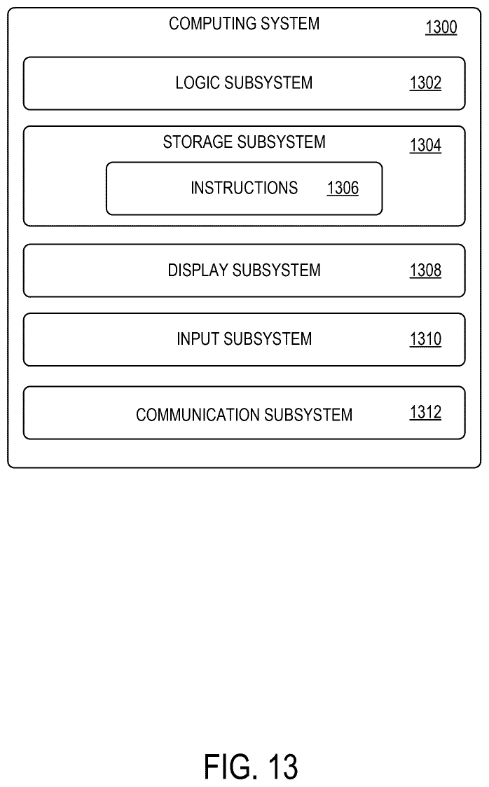

In some embodiments, the methods and processes described herein can be tied to a computing system of one or more computing devices. In particular, such methods and processes can be implemented as a computer-application program or service, an application-programming interface (API), a library, and/or other computer-program product. FIG. 13 schematically shows an example of a computing system 1300 that can enact one or more of the methods and processes described above. Computing system 1300 is shown in simplified form. Computing system 1300 can take the form of one or more personal computers, server computers, tablet computers, network computing devices, and/or other computing devices. Controllers 124 and 230 are examples of computing system 1300.

Computing system 1300 includes a logic subsystem 1302 and a storage subsystem 1304. Computing system 1300 can optionally include a display subsystem 1308, input subsystem 1310, communication subsystem 1312, and/or other components not shown in FIG. 13.

Logic subsystem 1302 includes one or more physical devices configured to execute instructions 1306. For example, the logic subsystem can be configured to execute instructions that are part of one or more applications, services, programs, routines, libraries, objects, components, data structures, or other logical constructs. Such instructions can be implemented to perform a task, implement a data type, transform the state of one or more components, achieve a technical effect, or otherwise arrive at a desired result. As examples, logic subsystem can execute instructions to implement method 200, method 500, and method 800.

The logic subsystem can include one or more processors configured to execute software instructions. Additionally or alternatively, the logic subsystem can include one or more hardware or firmware logic devices configured to execute hardware or firmware instructions. Processors of the logic subsystem can be single-core or multi-core, and the instructions executed thereon can be configured for sequential, parallel, and/or distributed processing. Individual components of the logic subsystem optionally can be distributed among two or more separate devices, which can be remotely located and/or configured for coordinated processing. Aspects of the logic subsystem can be virtualized and executed by remotely accessible, networked computing devices configured in a cloud-computing configuration.

Storage subsystem 1304 includes one or more physical devices configured to hold instructions 1306 executable by the logic subsystem to implement the methods and processes described herein. For example, storage subsystem 1304 can comprise instructions executable to perform method 200, method 500, and/or method 800. When such methods and processes are implemented, the state of storage subsystem 1304 can be transformed—e.g., to hold different data.

Storage subsystem 1304 can include removable and/or built-in devices. Storagesubsystem 1304 can include optical memory,, semiconductor memory,, and/or magnetic memory, among others. Storage subsystem 1304 can include volatile, nonvolatile, dynamic, static, read/write, read-only, random-access, sequential-access, location-addressable, file-addressable, and/or content-addressable devices.

It will be appreciated that storage subsystem 1304 includes one or more physical devices. However, aspects of the instructions described herein alternatively can be propagated by a communication medium (e.g., an electromagnetic signal, an optical signal, etc.) that is not held by a physical device for a finite duration.

Aspects of logic subsystem 1302 and storage subsystem 1304 can be integrated together into one or more hardware-logic components. Such hardware-logic components can include field-programmable gate arrays (FPGAs), program-and application-specific integrated circuits (PASIC / ASICs), program-and application-specific standard products (PSSP/ASSPs), system-on-a-chip (SOC), and complex programmable logic devices (CPLDs), for example.

When included, display subsystem 1308 can be used to present a visual representation of data held by storage subsystem 1304. This visual representation can take the form of a graphical user interface (GUI). As the herein described methods and processes change the data held by the storage subsystem, and thus transform the state of the storage subsystem, the state of display subsystem 1308 can likewise be transformed to visually represent changes in the underlying data. Display subsystem 1308 can include one or more display devices utilizing virtually any type of technology. Such display devices can be combined with logic subsystem 1302 and/or storage subsystem 1304 in a shared enclosure, or such display devices can be peripheral display devices.

When included, input subsystem 1310 can comprise one or more user-input devices such as a keyboard, mouse, or touch screen. In some embodiments, the input subsystem can comprise or interface with selected natural user input (NUI) componentry. Such componentry can be integrated or peripheral, and the transduction and/or processing of input actions can be handled on-or off-board.

When included, communication subsystem 1312 can be configured to communicatively couple computing system 1300 with one or more other computing devices. Communication subsystem 1312 can include wired and/or wireless communication devices compatible with one or more different communication protocols. As examples, the communication subsystem can be configured for communication using a wireless telephone network, or a wired or wireless local-or wide-area network. In some embodiments, the communication subsystem can allow computing system 1300 to send and/or receive messages to and/or from other devices using a network such as the Internet.

It will be understood that the configurations and/or approaches described herein are exemplary in nature, and that these specific embodiments or examples are not to be considered in a limiting sense, because numerous variations are possible. The specific routines or methods described herein may represent one or more of any number of processing strategies. As such, various acts illustrated and/or described may be performed in the sequence illustrated and/or described, in other sequences, in parallel, or omitted. Likewise, the order of the above-described processes may be changed.

The subject matter of the present disclosure includes all novel and non-obvious combinations and sub-combinations of the various processes, systems and configurations, and other features, functions, acts, and/or properties disclosed herein, as well as any and all equivalents thereof.

1. A method of performing atomic layer etching, the method comprising:
in a three-dimensional semiconductor device fabrication process, heating a substrate comprising a metal oxide layer within a recessed feature of the substrate; and
while heating the substrate, performing an atomic layer etching cycle comprising:
exposing the metal oxide layer within the recessed feature of the substrate to a fluorinating agent in the absence of a plasma to form a modified surface layer; and
exposing the modified surface layer to a volatilizing agent in the absence of the plasma to volatilize the modified surface layer.

2. The method of claim 1, wherein the fluorinating agent comprises one or more of hydrogen fluoride, a xenon fluoride, nitrogen trifluoride, a sulfur fluoride, an interhalogen fluoride, or molecular fluorine.

3. The method of claim 1, wherein the volatilizing agent comprises a chlorine donor, a methyl donor, or a bromine donor.

4. The method of claim 3, wherein the volatilizing agent comprises one or more of dimethyl aluminum chloride, trimethylaluminum, silicon tetrachloride, boron trichloride, trimethyl chlorosilane hydrogen bromide, trimethylbromosilane, bromosilane, thionyl bromide, sulfur bromide, phosphorus(III) bromide, phosphorus(V) bromide, or molecular bromine.

5. The method of claim 1, wherein heating the substrate comprises heating the substrate to a temperature of 170 degrees Celsius or higher.

6. The method of claim 1, wherein exposing the metal oxide layer to the fluorinating agent comprises exposing the metal oxide layer to a dose of the fluorinating agent of 0.05 Torr*s or higher.

7. The method of claim 6, wherein the recessed feature comprises an aspect ratio of 10:1 (depth:width) or higher.

8. The method of claim 1, wherein exposing the modified surface layer to the volatilizing agent comprises exposing the modified surface layer to a dose of the volatilizing agent of 0.35 Torr*s or higher.

9. The method of claim 1, wherein the atomic layer etching cycle comprises an etch rate uniformity as a function of depth within the recessed feature of greater than 85%.

10. The method of claim 1, wherein an etch per cycle (EPC) of the atomic layer etching cycle is greater than 0.10 nanometers/cycle.

11. A reactor for performing atomic layer etching, the reactor comprising:
a processing chamber;
a substrate holder comprising a heater; and
a controller comprising stored instructions that are executable to control the reactor to:
heat a substrate comprising a metal oxide layer within a recessed feature of the substrate; and
while heating the substrate, perform an atomic layer etching cycle by exposing the metal oxide layer within the recessed feature of the substrate to a fluorinating agent in the absence of a plasma to form a modified surface layer, and exposing the modified surface layer to a volatilizing agent in the absence of the plasma to volatilize the modified surface layer.

12. The reactor of claim 11, further comprising a fluorinating agent source, wherein the fluorinating agent source comprises one or more of hydrogen fluoride, a xenon fluoride, nitrogen trifluoride, a sulfur fluoride, an interhalogen fluoride, or molecular fluorine.

13. The reactor of claim 11, further comprising a volatilizing agent source, wherein the volatilizing agent source comprises a chlorine donor, a methyl donor, or a bromine donor.

14. The reactor of claim 13, wherein the volatilizing agent source comprises one or more of dimethyl aluminum chloride, trimethylaluminum, silicon tetrachloride, boron trichloride, trimethyl chlorosilane, hydrogen bromide, trimethylbromosilane, bromosilane, thionyl bromide, sulfur bromide, phosphorus(III) bromide, phosphorus(V) bromide, or molecular bromine.

15. The reactor of claim 11, wherein the instructions are executable to heat the substrate to a temperature greater than 170 degrees Celsius.

16. The reactor of claim 11, wherein the instructions are executable to expose the metal oxide layer to a dose of the fluorinating agent of 0.5 Torr*s or higher.

17. The reactor of claim 11, wherein the instructions are executable to expose the modified surface layer to a dose of the volatilizing agent of 0.35 Torr*s or higher.

18. The reactor of claim 11, wherein the instructions are executable to expose the metal oxide layer to the fluorinating agent by exposing the surface layer to a total pressure of 1 Torr or higher.

19. A method of performing atomic layer etching, the method comprising:
in a three-dimensional semiconductor device fabrication process, placing a substrate in a processing chamber, the substrate comprising a metal oxide layer as a surface layer within a recessed feature of the substrate;
heating the substrate to a temperature of 170 degrees Celsius or higher; and
while heating the substrate, performing an atomic layer etching cycle comprising:
exposing the metal oxide layer to a fluorinating agent in the absence of a plasma to form a modified surface layer, the metal oxide comprising a group 4 or group 5 transition metal; and
exposing the modified surface layer to a volatizing agent in the absence of a plasma at a dose selected to provide an etch rate uniformity as a function of depth within the recessed feature of greater than 85%.

20. The method of claim 19, wherein the etch per cycle (EPC) of the atomic layer etching cycle is greater than 0.10 nanometers/cycle.
